(19) United States
(12) Patent Application Publication
(10) Pub. No.: US 2007/0012938 A1
(43) Pub. Date: Jan. 18, 2007

(54) Light-emitting-diode packaging structure having thermal-electric element

(76) Inventors: Chih-Kuang Yu, Hsinchu (TW); Chun-Kai Liu, Hsinchu (TW); Ra-Min Tain, Hsinchu (TW); Jen-Hau Cheng, Hsinchu (TW)

Correspondence Address: HARNESS, DICKEY & PIERCE, P.L.C., P.O. BOX 8910, RESTON, VA, 20195, US

(21) Appl. No.: 11/255,915

(22) Filed: Oct. 24, 2005

(30) Foreign Application Priority Data
Jul. 15, 2005 (TW) 94124165

(51) Int. Cl. H01L 33/00

(52) U.S. Cl. 257/99

(57) ABSTRACT

A light-emitting-diode packaging structure having thermoelectric device, which is applied to the LED unit packaged using the flip chip technology. This is realized by directly building the thermoelectric elements into the solder bump layer of the light-emitting-diode packaging structure to replace a part of the solder bumps, as such raising the heat dissipation efficiency of the light emitting diode unit, enhancing the stability and reliability of light emission of the LED unit, and reducing the difficulties and complexity of the integration of the LED package.

This application claims the benefit of Taiwan Patent Application No. 94124165, filed on Jul. 15, 2005, which is hereby incorporated by reference for all purposes as if fully set forth herein.

### BACKGROUND OF THE INVENTION

1. Field of Invention

The invention relates to a light-emitting-diode (LED) packaging structure used for packaging an LED by means of flip-chip technology, and in particular to an LED packaging structure having thermoelectric elements, which is capable of enhancing the heat dissipation capability of the LED packing structure.

2. Related Art

In general, a light emitting diode (LED) is made of a semiconductor material, lights of various frequencies are generated by the LED through the combination of the electrons and holes in the semiconductor material into photons. In recent years, the LED has become ever more prominent and important as the light source of an illumination device and backlight of a displayer due to its excellent color purity, mercury-free, long service lift, and power savings. However, with the increasing illumination produced by the LED, the heat generated by the LED per unit area is raised, so that its heat generation intensity is increasing steadily. Meanwhile, the packing structure of the LED is different from that of the ordinary integrated circuit (IC), so that its packing and heat dissipation are not quite the same as those of the IC. Thus, presently, the technical problems and bottlenecks concerning the packaging and heat dissipation of the LED have to be solved urgently and expediently.

Usually, the electric connections in the LED can be realized by the following two methods: the wire bonding method or the flip-chip method. However, the drawback of the method does not have this problem. As shown in FIG. 1, in US Patent Case Number U.S. Pat. No. 6,483,196 is disclosed an LED 10 of a flip chip structure, wherein two solder bumps 11,12 are used for electrical connection, yet it does not furnish the design of heat dissipation.

Recently, in some of the researches it is suggested that solder bumps are used as thermal balls for heat dissipation. As such, heat dissipation of the solder bump is realized mainly by heat conduction through heat transfer, and heat is carried away through the heat dissipation fins disposed underneath. In the flip chip packaging of the LED, only two solder bumps are utilized for electrical connection and power input/output, and the remaining solder bumps are used exclusively as thermal balls, as such the heat generated by the LED is transferred to the substrate underneath through heat dissipation. However, the heat transfer capability is quite limited.

In addition, as shown in FIG. 2, in U.S. Pat. Case No. 6,455,878 is disclosed an LED 13 made by means of the flip chip technology, wherein the solder bumps, having no electric connection capability in the solder bump layer 14, are utilized as thermal balls 15 to transfer heat, thus achieving the objective of heat dissipation.

Furthermore, as shown FIG. 3, in U.S. Pat. Case No. 6,040,618 is disclosed a technology, wherein an additional bump 17 is made on a substrate 16 by means of a Micro-Electric-Mechanical method, such, that after bonding the flip chip, the gap between solder bump 18 and the substrate is filled by the bump 17 of the substrate 16, so that the contact area for heat transfer is increased, so as to provide heat conduction.

Moreover, as shown in FIG. 4, in U.S. Pat. Case No. 6,573,537 is disclosed a technology, wherein, an N-bond pad 19 and a P-bond pad 20 of a large area are used for heat transfer purpose.

In the above-mentioned description, though various passive heat dissipation methods are utilized in realizing the packaging structure of the LED, yet their heat dissipation effects are not quite satisfactory. Thus, a solid state active cooling type thermoelectric element may be utilized to provide the LED with more direct and efficient cooling capability.

The thermoelectric device is also called a cooler, which is an active type cooling device and can be used to dissipate heat and reduce the temperature of the electronic device below room temperature. The ordinary heat dissipation plate is a passive type cooling device, which is only able to provide the heat dissipation function when the temperature of the device to be cooled is higher than the temperature of the environment. Thus, in case the hot end of the thermoelectric device is connected to the similar heat dissipation plate, and since the thermoelectric device is utilized to conduct active type cooling, heat is successively removed from the cold end, thus the temperature of the cold end can be reduced to a temperature below room temperature and is thus suitable to be used for cooling the electronic element that generates a large amount of heat, as such greatly improves the performance of the electronic device. Consequently, this type of active cooling device may have an enormous competitive edge in the application of heat dissipation of electronic devices such as the LED packaging structure, due to its features and advantages of being capable of providing uninterrupted continuous operation without having to use any refrigerant, pollution free, no moving parts required, noise free, easy installation, light weight, and miniature size.

In this respect, in U.S. Pat. Case No. 5,832,015 is disclosed a heat dissipation method implemented by an integrated thermoelectric device, which is realized by first putting a thermoelectric device in a packaging frame made of material of good heat conduction but inferior electric conduction, next a laser diode module is placed on the packaging frame, then the chip wire is connected and a metallic protection cover is placed on the packaging frame, and finally integrating the heat dissipation fin into the packaging frame. However, this method is implemented by placing a thermoelectric device into a packaging frame, thus the heat dissipation efficiency is limited and not quite satisfactory.

### SUMMARY OF THE INVENTION

In view of the above-mentioned problems, the objective of the invention is to provide an LED packaging structure having a thermoelectric device, in which the thermoelectric device is utilized to replace the solder bumps having no power input/output capabilities and is directly made and integrated into the LED packaging structure, as such raising the heat dissipation efficiency of the LED elements, reducing the complexity and difficulties in the integration of the LED packaging structure, and thus solving the problems and shortcomings of the prior art.

Therefore, to achieve the above-mentioned objective, the invention discloses an LED packaging structure having thermoelectric device, including: an LED element, an insulation layer, a substrate, a solder bump layer, and a thermoelectric device having at least a pair of thermoelectric elements. The LED unit is electrically connected to the substrate through a solder bump layer, and the thermoelectric device is provided in the solder bump layer disposed between the LED unit and the substrate. An insulation layer is utilized to partially isolate the LED, the solder bump layer, and the thermoelectric element, and each thermoelectric element includes a p-type thermoelectric material element and an n-type thermoelectric material element, so that when a current flows through the thermoelectric element, the heat generated by the LED unit will be removed, a cool end is formed on a side of the LED unit, and a hot end is formed on a side of the substrate.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow illustration only, and thus are not limitative of the present invention, and wherein:

FIG. 1 is a schematic diagram of a light-emitting-diode (LED) packaging structure according to the prior art;

FIG. 2 is a schematic diagram of a structure of another LED packaging structure according to the prior art;

FIG. 3 is a schematic diagram of another LED packaging structure according to the prior art;

FIG. 4 is a schematic diagram of another LED packaging structure according to the prior art;

FIG. 5 is a schematic diagram of an LED packaging structure having a thermoelectric device according to an embodiment of the invention;

FIGS. 6A˜6E are the schematic diagrams of LED packaging structures having a thermoelectric device according to an embodiment of the invention, indicating the structures at various manufacturing processes; and

FIGS. 7˜16 are the schematic diagrams of LED packaging structures having a thermoelectric device according to other varied embodiments of the invention.

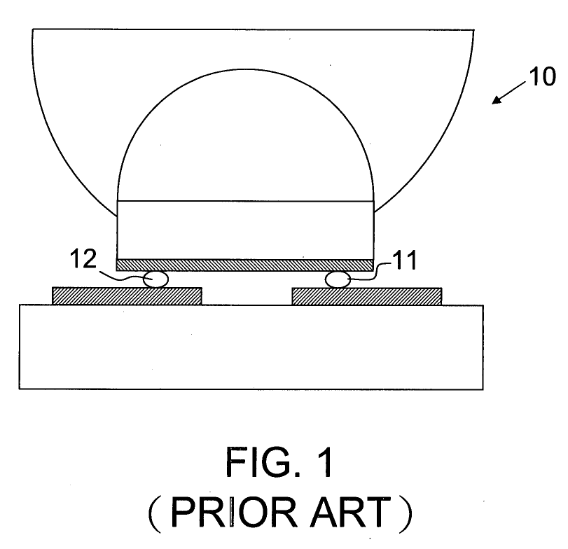

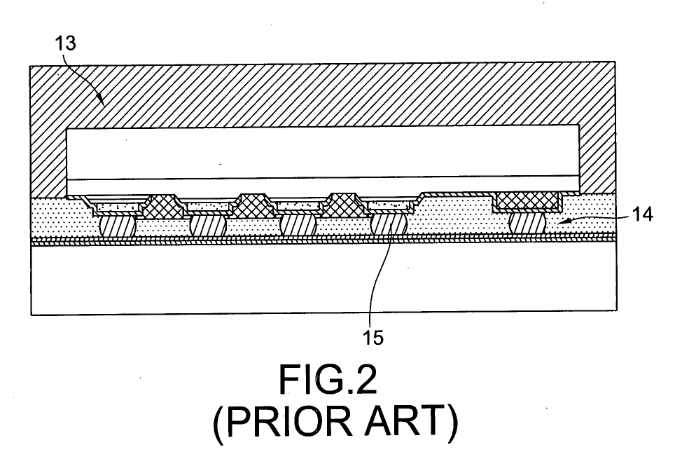

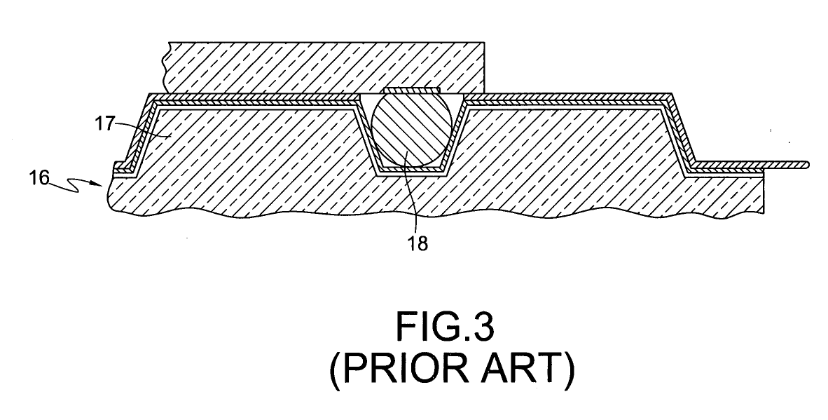

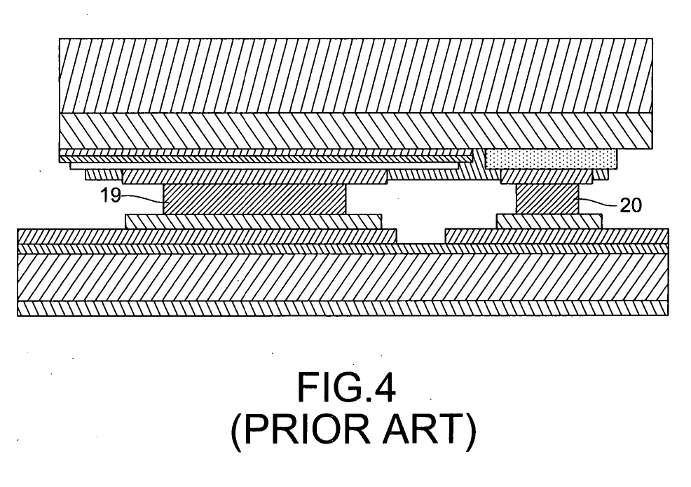

### DETAILED DESCRIPTION OF THE INVENTION

The purpose, construction, features, and functions of the invention can be appreciated and understood more thoroughly through the following detailed description with reference to the attached drawings.

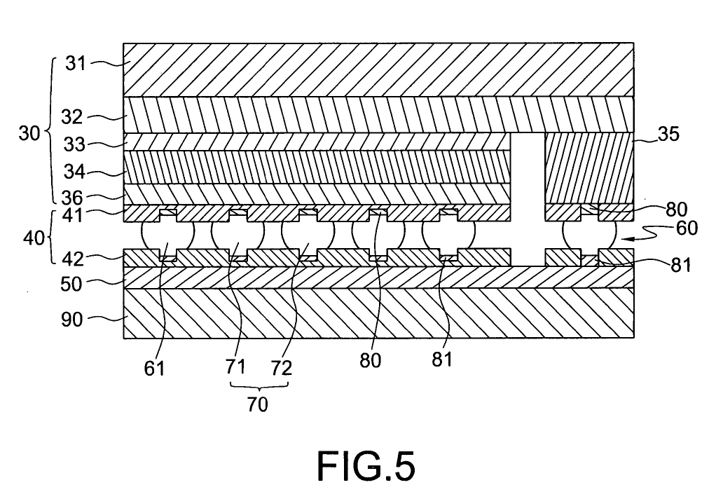

FIG. 5 is a schematic diagram of a light-emitting-diode (LED) packaging structure having a thermoelectric device according to an embodiment of the invention, including: a light-emitting-diode unit 30, an insulation layer 40, a substrate 50,a solder bump layer 60, and two sets of thermoelectric elements 70.

The light-emitting-diode unit 30 of the embodiment is formed by a p-type light emitting layer 32, an active layer 33, an n-type light emitting layer 34, a p-type contact layer 35, and an n-type contact layer 36 grown on a Sapphire substrate 31. In the above-mentioned structure, the p-type light emitting layer 32 is formed on the Sapphire substrate 31, the active layer 33 and the p-type contact layer 35 are formed on the p-type light emitting layer 32, the n-type light emitting layer 34 is formed on the active layer 33, the n-type contact layer 36 is formed on the n-type light emitting layer 34, the p-type contact layer 35 and the n-type contact layer 36 are connected respectively to a positive voltage source and a negative voltage source to lead in and provide the forward biased voltage, so that the holes from the p-type light emitting layer 32 and the electrons from the n-type light emitting layer 34 are combined in the active layer 33 to produce light. The light-emitting-diode unit 30 is flip-bonded on the substrate 50 through a solder bump layer 60 by means of the flip chip technology. In addition, the shape of the solder bump of the solder bump layer 60 is not restricted to any specific shape. It may be a round shape, square shape or any other shape depending on the actual requirements.

Furthermore, the thermoelectric elements 70 are composed of a p-type thermoelectric material element 71 and an n-type thermoelectric material elemenet 72, disposed in a solder bump layer 60 between the light-emitting-diode unit 30 and the substrate 50 in an interleaving arrangement. The insulation layer 40 is composed of an upper insulation layer 41 and a lower insulation layer 42 provided on the lower side of the light-emitting-diode unit 30 and the upper side of the substrate 50 respectively, and is used to isolate the above two items electrically and provide the circuit layers 80 and 81, used for wiring. By making use of the circuit layers 80 and 81, the light-emitting-diode unit 30 and the substrate 50 can be electrically connected through the solder bump layer 60, moreover, he light-emitting-diode unit 30 and the substrate 50 can be electrically connected through the p-type thermoelectric material unit 71 and the n-type thermoelectric material unit 72.

In the present embodiment, a heat dissipation module 90 is provided on the bottom of the substrate 50. Upon applying a forward-biased voltage, a current will flow from the light-emitting-diode unit 30 to the substrate 50 through the thermoelectric elements 70, to form a cold end on a side of the light-emitting-diode unit 30, and a hot end on a side of the substrate 50. As such, the heat generated by the light-emitting-diode unit 30 is efficiently transferred to the substrate 50 by means of the cold-end-heat-absorbing function of the thermoelectric elements 70, then the heat is removed and carried away through the heat dissipation module 90 disposed underneath the substrate 50, or, alternatively, the temperature of the light emitting diode unit 30 can be controlled at a specific temperature by making use of the temperature regulating function of the thermoelectric elements 70.

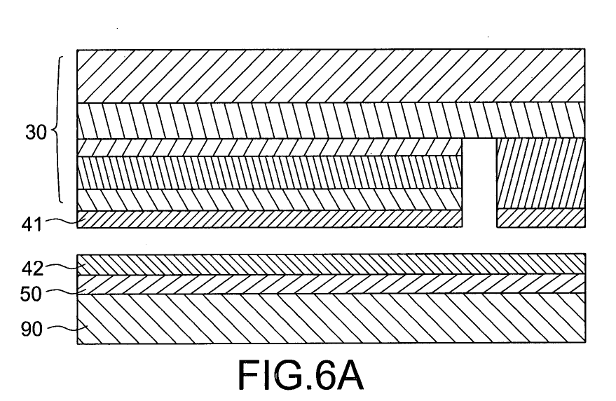

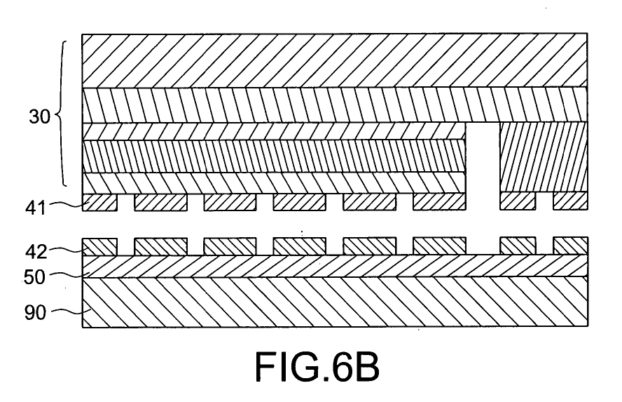

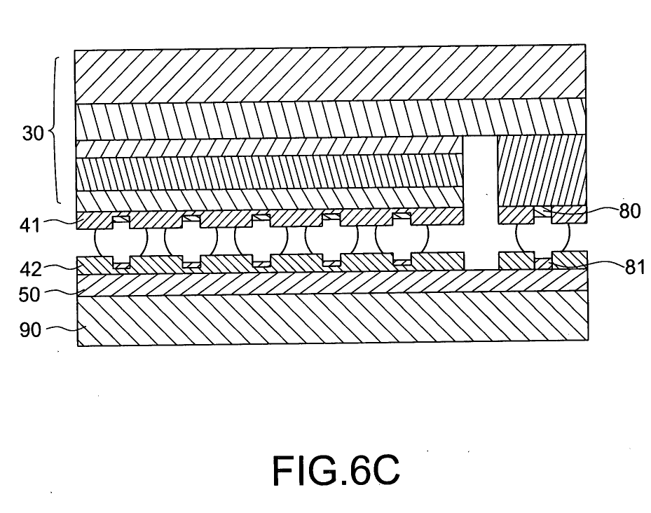

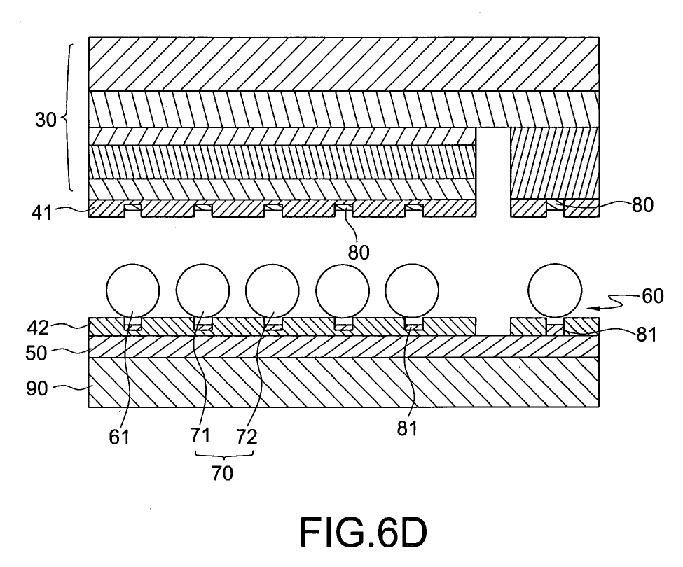

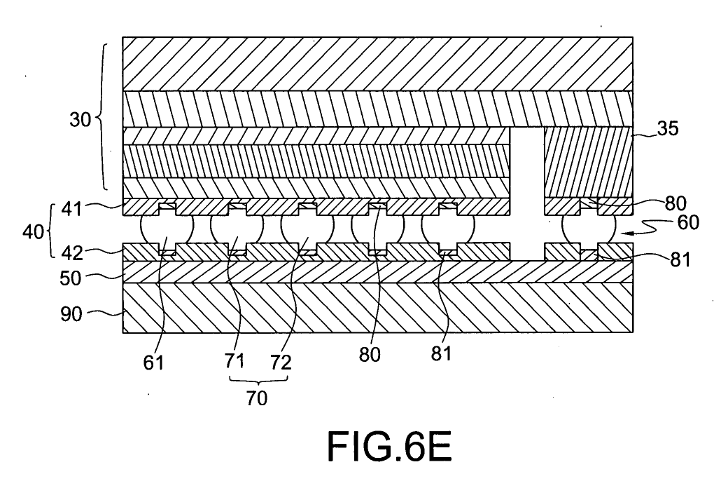

Subsequently, refer to FIGS. 6A˜6E for the schematic diagrams of a light emitting diode packaging structure having thermoelectric elements according to an embodiment of the invention, indicating the structures of various manufacturing processes.

FIGS. 6A to 6C show the light-emitting-diode packaging structure in the process of forming the insulation layer 40 and the circuit layers 80 and 81 on the substrate 50 and on the light-emitting-diode unit 30 respectively. Since the two processes are similar, in the following description, the process concerning the manufacturing of the light-emitting-diode unit 30 will be taken as an example to explain, to avoid repetition. Firstly, a glass protection layer is coated on the surface of the light-emitting-diode unit 30 as an insulation layer 41 (FIG. 6A), which is used to provide protective sealing and prevent wetting and spreading of the solder. Next, a plurality of through holes is opened on the solder bump layer 60 of the upper insulation layer 41 and the receiving pads of the thermoelectric elements 70. However, the through holes in the thermoelectric elements 70 do not penetrate through the upper insulation layer 41 (FIG. 6B). After wire channels of the thermoelectric elements 70 are opened in the upper insulation layer 41, it is sputtered on with a plurality of layers of metallic films made of chromium-copper-gold (usually referred to as Under Bump Metallurgy (UBM)), thus forming the circuit layer 80 (FIG. 6C) to provide the function of adhesion, spread prevention, solder wetting enhancement, and oxidation prevention. Then, the solder bumps 60 and the thermoelectric elements 70 are placed on the respective receiving pads on the substrate 50 by making use of the flip chip machine (FIG. 6D). Subsequently, the light-emitting-diode unit 30 is bonded onto the receiving pads disposed on the substrate 50 through precise alignment (FIG. 6E). Finally, fixing and securing the solder bumps 60 into their positions through the application of reflow, as such realizing the manufacturing of a light-emitting-diode packaging structure having the thermoelectric device of the invention.

In the above description, the thermoelectric elements 70 is made by means of micro electric mechanical processing, semiconductor processing, precision machinery processing or other manufacturing processing. Besides, the assembly of the thermoelectric elements 70 is achieved through the flip-chip technology, screen printing method or the like. Moreover, the attaching of thermoelectric elements 70 on the solder bump layer 60 is realized through sputtering, evaporation, electroplating or the like.

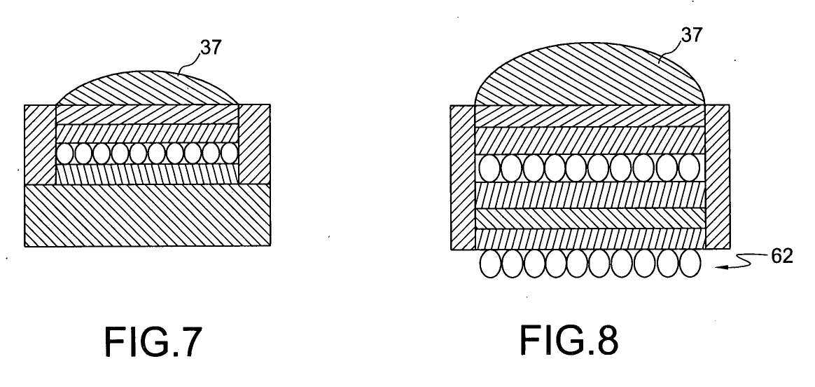

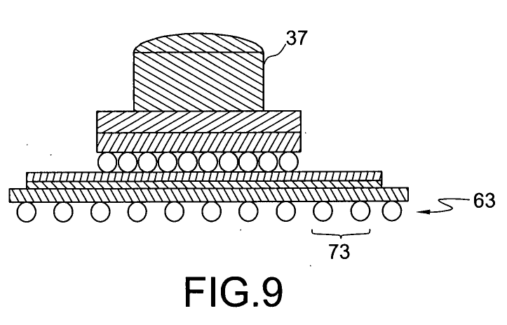

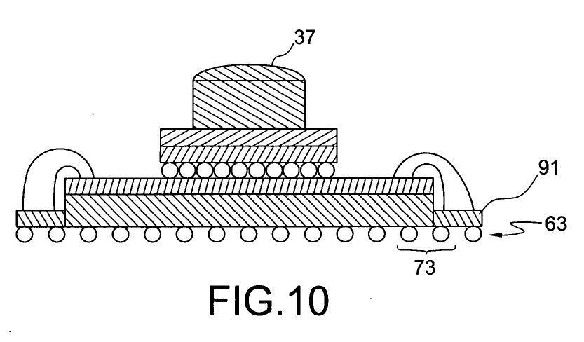

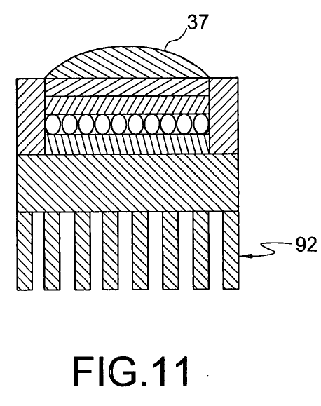

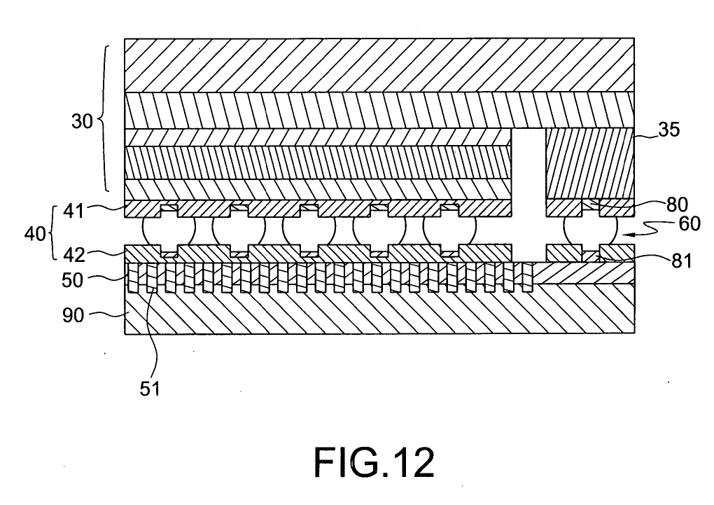

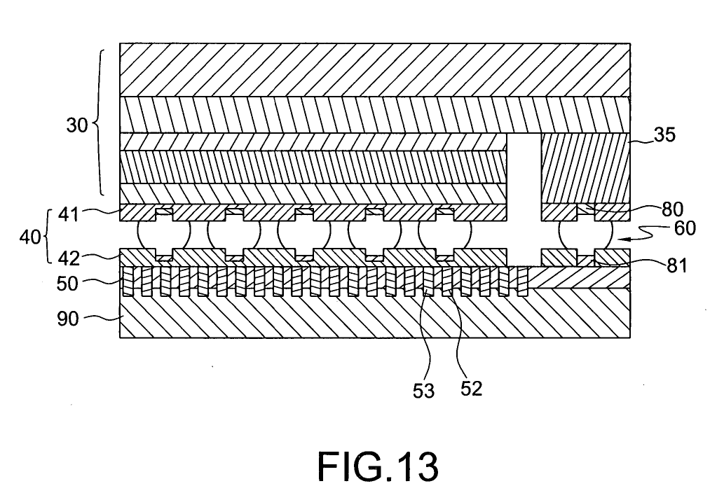

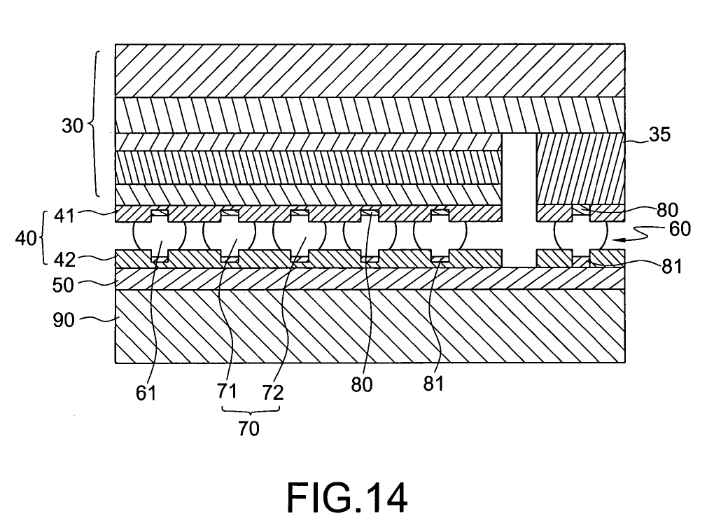

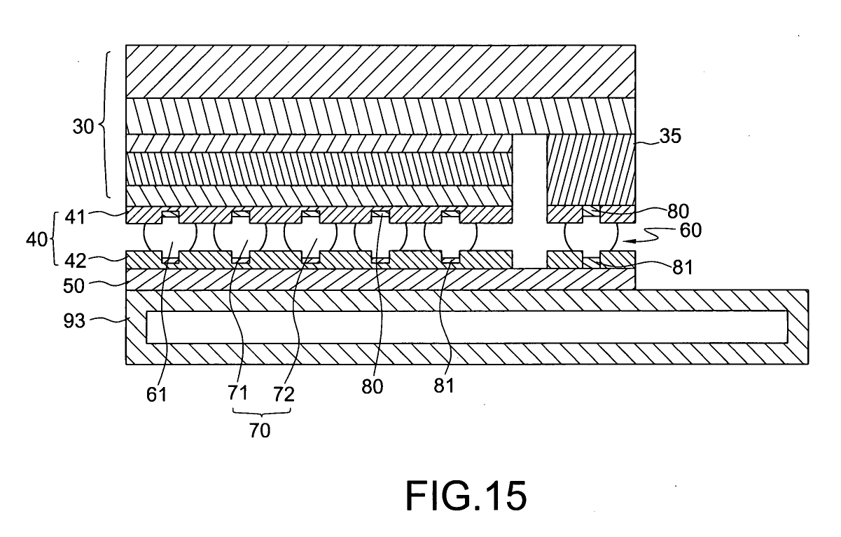

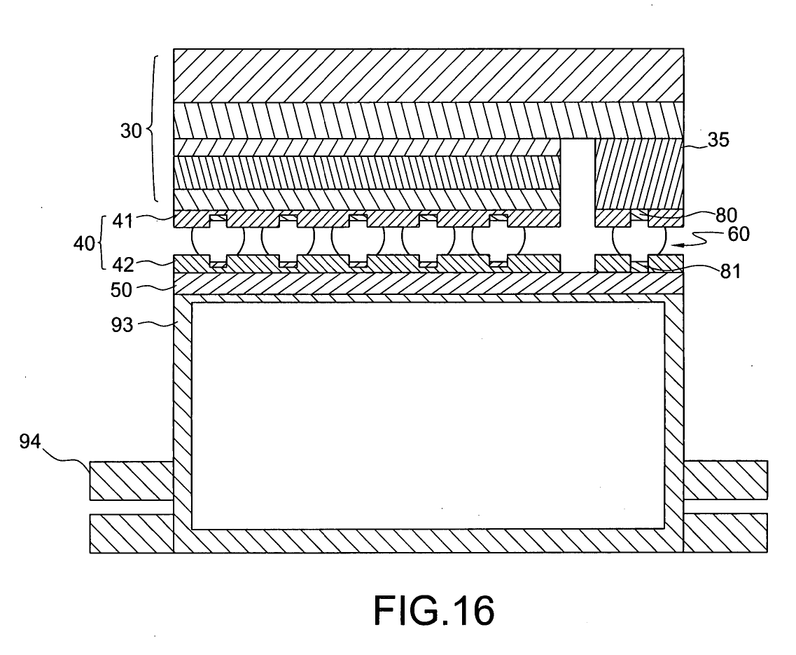

Besides, as shown in FIG. 7, the light-emitting-diode packaging structure of the present embodiment further includes a mirror body 37, which is used to raise the overall luminance of the LED packaging structure. Moreover, as shown in FIG. 8, another solder bump layer 62 may be provided underneath the LED packaging structure to be connected to another device. Alternatively, as shown in FIG. 9, a plurality of pairs of thermoelectric device 73 may be disposed in the solder bump layer 63, thus increasing the overall heat dissipation effect of the LED packaging structure.

Furthermore, as shown in FIG. 10, another element 91 may be connected to the LED packaging structure by means of wire bonding, and this element 91 may be connected to other elements through the solder bump layer 63. And as shown in FIG. 11, the LED packaging structure may be connected to other elements through a plurality of pins 92 disposed underneath.

Refer to FIG. 12, showing a plurality of thermal vias 51, which may be provided in the substrate 50 to increase the heat conduction capability of the substrate 50, so that heat can be transferred faster to the heat dissipation module 90 provided at the bottom of the LED packaging structure. Further, refer to FIG. 13, a thermoelectric material may be placed into the thermal vias 51 by means of electroplating, bulk-material placing, fluid injection, etc., to form the second set (order) of the thermoelectric unit, including the p-type thermoelectric material unit 52 and the n-type thermoelectric material unit 53, as shown in the drawing, in the substrate 50 to further raise the heat conduction capability of the LED packaging structure.

Alternatively, refer to FIG. 14, in which the substrate 50 is omitted, instead the whole set of light emitting diodes along with the thermoelectric unit are disposed directly on the heat dissipation module 90, and its surface is coated with a layer of anode-processed insulation (it may be a thin film or a thick film). The insulation layer may be made by an oxidation or anode-processing method etc. As such, the structure thus obtained may significantly reduce the contact resistance between the light-emitting-diode and the heat dissipation module, and raise the operation efficiency of the thermoelectric device. Meanwhile, the heat dissipation module 90 may be made into the shape of a heat pipe 93, as shown in FIG. 15, wherein the surface of a side of the heat pipe 93 connected to the thermoelectric device is coated with an insulation layer (it may be a thin film or a thick film), that may likewise be made by oxidation or anode-processing method. As such, the packaging structure thus obtained may significantly reduce the related contact resistance, meanwhile, it may control the temperature of the hot end within a specific range, and increase the operation efficiency of the thermoelectric device. Of course, as shown in FIG. 16, in this packaging structure, the size of the heat pipe 93 may be enlarged, and a heat dissipation fin 94 may be attached outside, thus further enhancing the heat dissipation effect.

Summing up the above, the innovative approach and solution adopted by the invention is to build the thermoelectric device directly into the solder bump layer during the manufacturing of the LED packaging structure. It makes use of the concept of integrating the heat dissipation design into the packaging structure, rather than attaching the heat dissipation elements required for the packaging structure after its completion.

Therefore, through the application of the invention, the difficulties and complexity of integrating the thermoelectric device into the chip package of the prior art can be significantly reduced, meanwhile the problem of the hot spot can be solved, and the related contact resistance can be reduced, thus enhancing the stability and reliability of the operation of the LED packaging structure, which as such is compatible with the trend of the development of the LED packaging structure.

Knowing the invention being thus described, it will be obvious that the same may be varied in many ways. Such variations are not to be regarded as a departure from the spirit and scope of the invention, and all such modifications as would be obvious to one skilled in

the art are intended to be included within the scope of the following claims.

What is claimed is:

1. A light-emitting-diode (LED) packaging structure having thermoelectric device, comprising:
a light-emitting-diode unit;
an insulating layer, disposed in said light-emitting-diode unit;
a substrate, used to accommodate said light-emitting-diode unit and said insulation layer;
a solder bump layer, disposed between said light-emitting-diode unit and said substrate to electrically connect said light-emitting-diode unit and said substrate; and
a thermoelectric device including at least a pair of thermoelectric elements and disposed in said solder bump layer between said insulation layer and said substrate, said pair of thermoelectric elements includes an electrically connected p-type thermoelectric material element and a n-type thermoelectric material element, thus forming a cold end on a side of said light-emitting-diode unit, and a hot end on a side of said substrate.

2. The light-emitting-diode (LED) packaging structure having thermoelectric device as claimed in claim 1, further comprising an electric circuit layer disposed between said light-emitting-diode unit and said substrate so that: said light-emitting-diode unit is electrically connected to said substrate through said solder bump layer; said p-type thermoelectric material element of said thermoelectric device is electrically connected to said n-type thermoelectric material element; and said p-type thermoelectric material element and said n-type thermoelectric material element are electrically connected to said light-emitting-diode unit and said substrate respectively, as such forming said cold end and said hot end.

3. The light-emitting-diode (LED) packaging structure having thermoelectric device as claimed in claim 1, wherein said p-type thermoelectric material element and said n-type thermoelectric material element are disposed in a mutually interleaving arrangement.

4. The light-emitting-diode (LED) packaging structure having thermoelectric device as claimed in claim 1, wherein a set of thermoelectric elements are disposed underneath said substrate.

5. The light-emitting-diode (LED) packaging structure having thermoelectric device as claimed in claim 1, wherein a plurality of thermal vias are provided in said substrate.

6. The light-emitting-diode (LED) packaging structure having thermoelectric elements as claimed in claim 5, wherein another thermoelectric element is included in said thermal via.

7. A light-emitting-diode (LED) packaging structure having thermoelectric device, comprising:
a light-emitting-diode unit;
an insulating layer, disposed in said light-emitting-diode unit;
a heat dissipation module, used to accommodate said insulation layer and said light-emitting-diode unit;
a circuit layer, disposed between said light-emitting-diode unit and said heat dissipation module;
a solder bump layer, disposed between said light-emitting-diode unit and said circuit layer to electrically connect said light-emitting-diode unit and said circuit layer; and
a thermoelectric device including at least a pair of thermoelectric elements and disposed in said solder bump layer between said insulation layer and said heat dissipation module, said pair of thermoelectric units include an electrically connected p-type thermoelectric material unit and a n-type thermoelectric material unit, thus forming a cold end on a side of said light-emitting-diode unit, and a hot end on a side of said substrate.

8. The light-emitting-diode (LED) packaging structure having thermoelectric device as claimed in claim 7, wherein said p-type thermoelectric material element and said n-type thermoelectric material element are disposed in a mutually interleaving arrangement.

9. The light-emitting-diode (LED) packaging structure having thermoelectric device as claimed in claim 7, wherein said heat dissipation module is a heat pipe.

10. The light-emitting-diode (LED) packaging structure having thermoelectric device as claimed in claim 7, wherein a plurality of heat dissipation fins are attached outside said heat dissipation module.
